(19) United States
(12) Patent Application Publication
(10) Pub. No.: US 2012/0256640 A1
(43) Pub. Date: Oct. 11, 2012

(54) APPARATUS AND METHODS FOR USE IN DETERMINING THE PRESENCE OF MATERIALS ENTRAINED WITHIN A MEDIUM

(76) Inventor: Boris Leonid Sheikman, Minden, NV (US)

(21) Appl. No.: 13/081,876

(22) Filed: Apr. 7, 2011

(51) Int. Cl. G01R 27/04

(52) U.S. Cl. 324/637

(57) ABSTRACT

A method for determining a presence of at least one material entrained within a medium is provided. The method includes transmitting at least one microwave signal to a microwave emitter. At least one electromagnetic field is generated by the microwave emitter from the microwave signal. A change in the dielectric constant for the medium at a frequency received from the microwave emitter is detected. Moreover, an expected power level of the frequency received from the microwave emitter is compared with an actual power level of the frequency to determine the presence of the material entrained within the medium.

### BACKGROUND OF THE INVENTION

The field of the invention relates generally to power generation systems, and more particularly, to sensor assemblies and methods for use in determining the presence of materials within a medium using a microwave emitter.

At least some known power generation systems include one or more components that may become damaged or worn over time. For example, at least some known power generation systems include electrical transformers. Moreover, at least some known electrical transformers include oil that is contained within the transformer to cool the transformer and to provide electrical insulation. Over time, the quality of the oil may change and the oil may have contaminants. For example, the oil may dissociate into various gaseous components that are dissolved within the oil. Continued operation with aged oil may cause damage to the transformer, such as the wiring within the transformer, and/or may lead to a premature failure of the transformer and/or system. As such, conducting regular testing of the oil within a transformer is essential.

One way to measure oil quality is by measuring the dielectric constant. For example, changes in the dielectric constant of an old oil sample compared to a new oil sample may indicate the presence of contaminants entrained within the oil, such as dissolved gases, water or particles, or changes in the chemistry of the oil, such as additive depletion or oxidation. When a change in the dielectric constant is detected for an oil sample, the types of contaminants within the oil sample may also be detected. For example, to detect the presence of dissolved gases within a transformer, at least some known sensor systems may be used. Some of such sensor systems use in-line probe measurements to determine the presence of dissolved gases within the transformer. For example, after obtaining a sample of oil from within the transformer, a spectrometer is used to analyze the oil. More specifically, the spectrometer analyzes the sample against a standard that includes a new and uncontaminated oil sample. Such sensor systems provide sufficient information to identify the various gas components within the oil. However, such systems may be tedious and costly, as the analysis is generally performed in a location remote from the transformer. Moreover, by having to take the sample of oil to another location, the sensor systems are unable to provide real time data.

### BRIEF DESCRIPTION OF THE INVENTION

In one embodiment, a method for determining a presence of at least one material entrained within a medium is provided. The method includes transmitting at least one microwave signal to a microwave emitter. At least one electromagnetic field is generated by the microwave emitter from the microwave signal. A change in the dielectric constant for the medium at a frequency received from the microwave emitter is detected. Moreover, an expected power level of the frequency received from the microwave emitter is compared with an actual power level of the frequency to determine the presence of the material entrained within the medium.

In another embodiment, a sensor assembly for use with a power generation system is provided. The sensor assembly includes at least one probe that includes a microwave emitter, wherein the microwave emitter is configured to generate at least one electromagnetic field from at least one microwave signal. Moreover, the sensor assembly includes at least one signal processing device that is coupled to the probe. The signal processing device is configured to detect a change in the dielectric constant for a medium at a frequency received from the microwave emitter and to compare an expected power level of the frequency received from the microwave emitter with an actual power level of the frequency in order to determine a presence of at least one material entrained within the medium.

In yet another embodiment, a power generation system is provided. The power generation system includes a machine that includes at least one transformer, wherein the transformer includes a medium contained therein. A sensor assembly is positioned proximate to the transformer. The sensor assembly includes at least one probe that includes a microwave emitter, wherein the microwave emitter is configured to generate at least one electromagnetic field from at least one microwave signal. Moreover, the sensor assembly includes at least one signal processing device that is coupled to the probe. The signal processing device is configured to detect a change in the dielectric constant for the medium at a frequency received from the microwave emitter and to compare an expected power level of the frequency received from the microwave emitter with an actual power level of the frequency in order to determine a presence of at least one material entrained within the medium.

### BRIEF DESCRIPTION OF THE DRAWINGS

FIG. 1 is a block diagram of an exemplary power generation system;

FIG. 2 is a block diagram of an exemplary sensor assembly that may be used with the power generation system shown in FIG. 1;

FIG. 3 is a graphical view of an exemplary power difference response that may be generated by the sensor assembly shown in FIG. 2; and

FIG. 4 is a flow diagram of an exemplary method that may be used to determine the presence of materials within a medium using the sensor assembly shown in FIG. 2.

### DETAILED DESCRIPTION OF THE INVENTION

The exemplary methods, apparatus, and systems described herein overcome at least some disadvantages associated with known sensor systems for transformers. In particular, the embodiments described herein provide a sensor assembly that detects a change of the dielectric constant for a medium and determines the presence of at least one material within the medium in real-time that is the cause for the change in the dielectric constant. More specifically, the sensor assembly includes a probe that includes a microwave emitter, and at least one signal processing device that is coupled to the probe. The signal processing device is configured to detect a change in the dielectric constant for a medium at a frequency received from the microwave emitter and to compare an expected power level of the frequency received from the microwave emitter with an actual power level of the frequency in order to determine a presence of at least one material entrained within the medium. This comparison enables the sensor assembly to determine the presence of any gaseous components within the oil in a transformer.

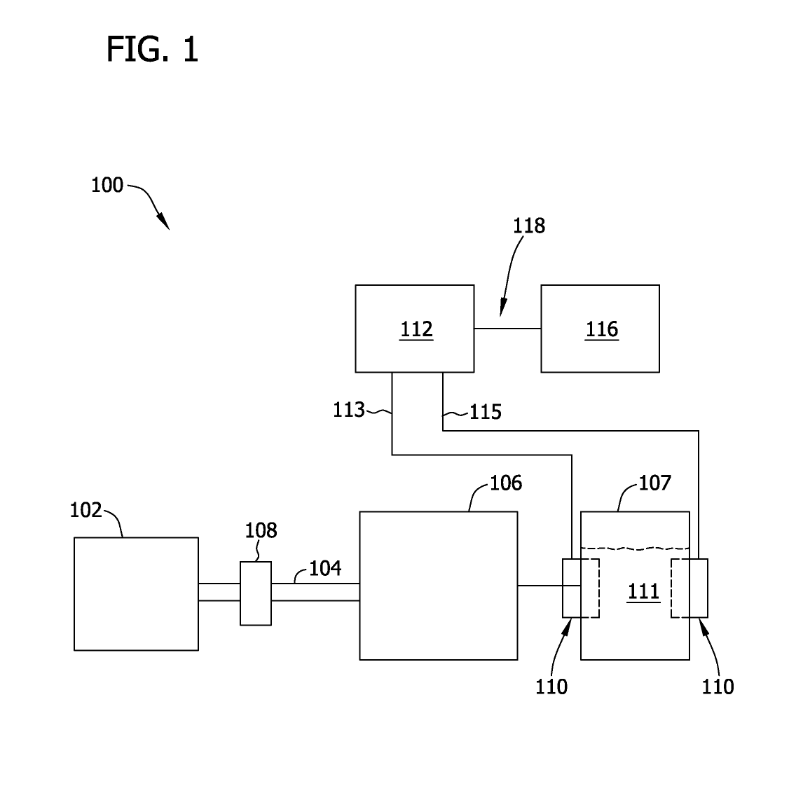

FIG. 1 illustrates an exemplary power generation system 100 that includes a machine 102, such as, but not limited to a wind turbine, a hydroelectric steam turbine, a gas turbine, and/or a compressor. In the exemplary embodiment, machine 102 rotates a drive shaft 104 coupled to a load 106, such as a generator. Moreover, load 106 is coupled to at least one transformer 107. In the exemplary embodiment, transformer 107 may be either a step up or a step down transformer. Moreover, it should be noted that, as used herein, the term “couple” is not limited to a direct mechanical and/or an electrical connection between components, but may also include an indirect mechanical and/or electrical connection between multiple components.

In the exemplary embodiment, drive shaft 104 is at least partially supported by one or more bearings (not shown) housed within machine 102 and/or within load 106. Alternatively or additionally, the bearings may be housed within a separate support structure 108, such as a gearbox, or any other structure that enables power generation system 100 to function as described herein.

In the exemplary embodiment, power generation system 100 includes at least one sensor assembly 110 that measures and/or monitors a medium 111 contained within transformer 107. In the exemplary embodiment, medium 111 is a liquid medium. More specifically, in the exemplary embodiment, medium 111 is oil. Alternatively, medium 111 may be any other type of medium that enables transformer 107 and system 100 to function as described herein.

Moreover, in the exemplary embodiment, sensor assembly 110 is positioned in close proximity to transformer 107 such that a microwave emitter (not shown in FIG. 1) that is a component of sensor assembly 110 is at least partially submerged within medium 111. In the exemplary embodiment, sensor assembly 110 measures and/or monitors the presence of at least one material (not shown), such as a gaseous component, within medium 111. As explained in more detail below, in the exemplary embodiment, sensor assembly 110 uses one or more microwave signals to detect a change in the dielectric constant of medium 111 at a frequency received from the microwave emitter and to compare an expected power level of the frequency received from the microwave emitter with an actual power level of the frequency in order to determine a presence of any gaseous components within medium 111. In the exemplary embodiment, the results of this comparison are referred to as a “power difference response” (not shown in FIG. 1) of sensor assembly 110. Alternatively, sensor assembly 110 may be used to measure and/or monitor any other component of power generation system 100, and/or may be any other sensor or transducer assembly that enables system 100 to function as described herein. As used herein, the term “microwave” refers to a signal or a component that receives and/or transmits signals having frequencies between about 300 Megahertz (MHz) and to about 300 Gigahertz (GHz).

Moreover, in the exemplary embodiment, power generation system 100 includes a diagnostic system 112 that is coupled to one or more sensor assemblies 110. Diagnostic system 112 processes and/or analyzes one or more signals generated by sensor assemblies 110. As used herein, the term “process” refers to performing an operation on, adjusting, filtering, buffering, and/or altering at least one characteristic of a signal. More specifically, in the exemplary embodiment, sensor assemblies 110 are coupled to diagnostic system 112 via a data conduit 113 or a data conduit 115. Alternatively, sensor assemblies 110 may be wirelessly coupled to diagnostic system 112.

After diagnostic system 112 processes and/or analyzes the signals generated from sensor assemblies 110, diagnostic system 112 then transmits the processed signals to a display device 116, included in power generation system 100. Display device 116 is coupled to diagnostic system 112 via a data conduit 118. More specifically, in the exemplary embodiment, the signals are transmitted to display device 116 via data conduit 118 for display or output to a user. Alternatively, display device 116 may be wirelessly coupled to diagnostic system 112.

During operation, in the exemplary embodiment, because of the age of medium 111, for example, medium 111 may dissociate into various gaseous components that are dissolved within medium 111, thus resulting in a resonant frequency shift of liquid medium 111 and a change in the dielectric constant for medium 111. In the exemplary embodiment, sensor assemblies 110 measure and/or monitor resonant frequency shifts and/or changes in the amplitude of the electromagnetic response within liquid medium 111 to detect and/or identify a change in the dielectric constant for medium 111. Sensor assemblies 110 also generate a signal representative of a comparison between an expected power level of a frequency received from the microwave emitter, and an actual power level of the frequency (hereinafter referred to as the “power difference signal”). The power level signal is transmitted to diagnostic system 112 for processing and/or analysis. After diagnostic system 112 processes and/or analyzes the power level signal, the power level signal is then transmitted to display device 116 for display or output to a user. The power difference signal enables the user to identify a presence of at least one material entrained within medium 111.

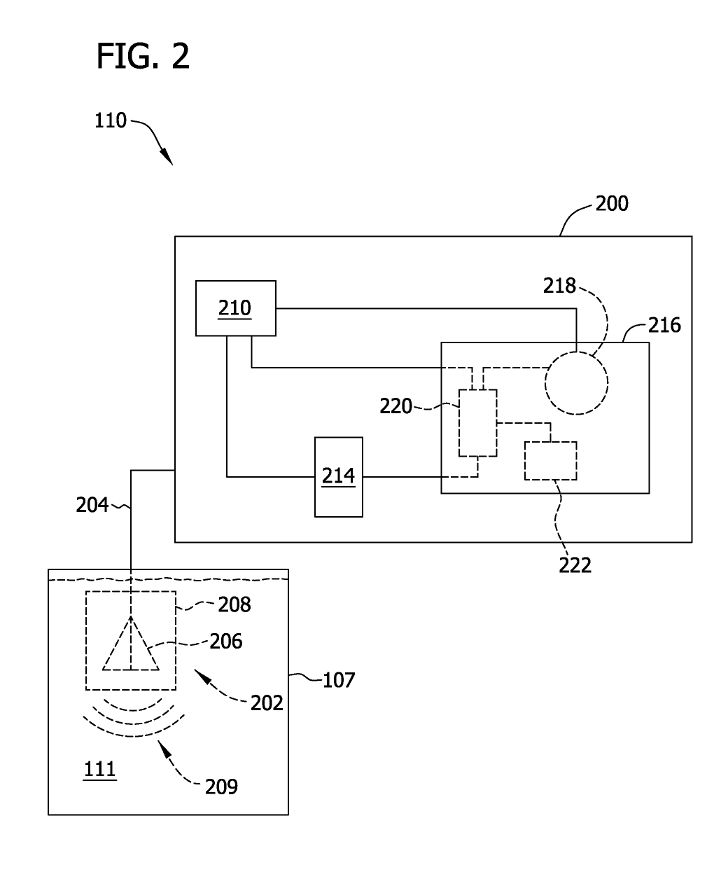

FIG. 2 is a schematic diagram of sensor assembly 110. In the exemplary embodiment, sensor assembly 110 includes a signal processing device 200 and a probe 202 that is coupled to signal processing device 200 via a data conduit 204. Alternatively, probe 202 may be wirelessly coupled to signal processing device 200.

Moreover, in the exemplary embodiment, probe 202 includes an emitter 206 that is coupled to and/or positioned within a probe housing 208 for generating at least one electromagnetic field 209. Emitter 206 is coupled to signal processing device 200 via data conduit 204. Alternatively, emitter 206 may be wirelessly coupled to signal processing device 200. Moreover, in the exemplary embodiment, probe 202 is submerged within medium 111. More specifically, in the exemplary embodiment, emitter 206 and probe housing 208 are submerged within liquid medium 111. Moreover, in the exemplary embodiment, probe 202 is a microwave probe 202 that includes a microwave emitter 206. Emitter 206 generates electromagnetic field 209 from at least one microwave signal that includes a plurality of frequency components within a predefined frequency range. More specifically, in the exemplary embodiment, microwave emitter 206 is a broadband emitter that receives and/or transmits signals having frequencies between approximately 1 GHz and approximately 20 GHz.

Moreover, in the exemplary embodiment, signal processing device 200 includes a directional coupling device 210 that is coupled to a reception power detector 214 and to a signal conditioning device 216. Furthermore, in the exemplary embodiment, signal conditioning device 216 includes a signal generator 218, a subtractor 220, and a memory device 222.

In the exemplary embodiment, memory device 222 enables information such as executable instructions and/or other data to be stored and retrieved. Memory device 222 may include one or more computer readable media, such as, without limitation, dynamic random access memory (DRAM), static random access memory (SRAM), a solid state disk, and/or a hard disk. Memory device 222 may be configured to store, without limitation, executable instructions, configuration data, geographic data (e.g., topography data and/or obstructions), utility network equipment data, and/or any other type of data.

More specifically, in the exemplary embodiment, memory device 222 stores expected power levels for each frequency level from between approximately 1 GHz and 20 GHz for a standard clean and uncontaminated oil sample that may be used in transformer 107. Moreover, in the exemplary embodiment, memory device 222 may include random access memory (RAM), which can include non-volatile RAM (NVRAM), magnetic RAM (MRAM), ferroelectric RAM (FeRAM) and other forms of memory. Memory device 222 may also include read only memory (ROM), flash memory and/or Electrically Erasable Programmable Read Only Memory (EEPROM). Any other suitable magnetic, optical and/or semiconductor memory, by itself or in combination with other forms of memory, may be included in memory device 222.

Memory device 222 may also be, or include, a detachable or removable memory, including, but not limited to, a suitable cartridge, disk, CD ROM, DVD or USB memory. Moreover, memory device 222 may be a database. The term “database” refers generally to any collection of data including hierarchical databases, relational databases, flat file databases, object-relational databases, object oriented databases, and any other structured collection of records or data that is stored in a computer system. The above examples are exemplary only, and thus are not intended to limit in any way the definition and/or meaning of the term database. Examples of databases include, but are not limited to only including, Oracle® Database, MySQL, IBM® DB2, Microsoft® SQL Server, Sybase®, and PostgreSQL. However, any database may be used that enables the systems and methods described herein. (Oracle is a registered trademark of Oracle Corporation, Redwood Shores, Calif.; IBM is a registered trademark of International Business Machines Corporation, Armonk, N.Y.; Microsoft is a registered trademark of Microsoft Corporation, Redmond, Wash.; and Sybase is a registered trademark of Sybase, Dublin, Calif.)

During operation, in the exemplary embodiment, signal generator 218 generates at least one electrical signal having a microwave frequency (hereinafter referred to as a “microwave signal”). Signal generator 218 transmits the microwave signal to directional coupling device 210. More specifically, in the exemplary embodiment, signal generator 218 transmits microwave signals incrementally to directional coupling device 210, wherein the first microwave signal transmitted includes a frequency component of approximately 1 GHz and the final microwave signal transmitted includes a frequency component of approximately 20 GHz. Alternatively, signal generator 218 may transmit microwave signals to directional coupling device 210 in any manner such that sensor assemblies 110 and/or power generation system 100 (shown in FIG. 1) may function as described herein.

Directional coupling device 210 then transmits each microwave signal to emitter 206. As each microwave signal is transmitted through emitter 206, electromagnetic field 209 is emitted from emitter 206 and out of probe housing 208. If a gaseous component (not shown) enters electromagnetic field 209, an electromagnetic coupling may occur between the gaseous component and field 209. More specifically, the presence of the gaseous component within electromagnetic field 209 and the dielectric constant of the gaseous component, which is different from the dielectric constant of a standard clean and uncontaminated oil sample, disrupt electromagnetic field 209 because of an induction and/or capacitive effect within the gaseous component. Such a disruption may cause at least a portion of electromagnetic field 209 to be inductively and/or capacitively coupled to the gaseous component as an electrical current and/or charge. In such an instance, emitter 206 is detuned (i.e., a resonant frequency of emitter 206 is reduced and/or changed, etc.) and a loading is induced to emitter 206. The loading induced to emitter 206 causes a reflection of the microwave signal (hereinafter referred to as a “detuned loading signal”) to be transmitted through data conduit 204 to directional coupling device 210. Moreover, in the exemplary embodiment, a detuned loading signal may be generated for each microwave signal that is transmitted through emitter 206.

In the exemplary embodiment, each detuned loading signal has a different power amplitude and/or a different phase than the power amplitude and/or the phase of the microwave signal. Moreover, in the exemplary embodiment, the power amplitude of each detuned loading signal is dependent upon the presence of each gaseous component within medium 111 and/or the quantity of each gaseous component within medium 111.

Directional coupling device 210 transmits each detuned loading signal to reception power detector 214. In the exemplary embodiment, reception power detector 214 measures an amount of power contained in each detuned loading signal and transmits a signal representative of each measured detuned loading signal power (hereinafter referred to as the “actual power level signal”) to signal conditioning device 216. Moreover, at the same time, memory device 222 transmits a signal representative of each expected power level for each frequency level from between approximately 1 GHz and 20 GHz for a standard clean and uncontaminated oil sample that may be used in transformer 107 (hereinafter referred to as the “expected power level signal”) to subtractor 220.

In the exemplary embodiment, subtractor 220 receives the actual power level signal and the expected power level signal, and calculates a difference between each actual power level and each expected power level received. If the difference between each actual power level and each expected power level is approximately zero, then there is no change in the dielectric constant for medium 111 and as a result, medium 111 does not contain gaseous components therein and/or the presence of gaseous components within medium 111 is minimal. Alternatively, if the difference between each actual power level and each expected power level is greater than zero, then there is a change in the dielectric constant for medium 111 and as a result, there is a presence of gaseous components within medium 111.

Subtractor 220 transmits a signal representative of each calculated difference (i.e., “power difference signal”) to diagnostic system 112 (shown in FIG. 1). In the exemplary embodiment, an amplitude of the power difference signal is substantially proportional, such as inversely proportional or exponentially proportional, to the shift in resonant frequency between the gaseous component within electromagnetic field 209 and probe 202. Moreover, in the exemplary embodiment, subtractor 220 transmits each power difference signal to diagnostic system 112 with a scale factor enabled for processing and/or analysis within diagnostic system 112. Subtractor 220 can utilize either analog or digital signal processing techniques as well as using a hybrid mix of the two.

In the exemplary embodiment, diagnostic system 112, may transmit, via conduit 118 (shown in FIG. 1), a signal representative of the resonant frequency shifts and/or changes in the amplitude of the electromagnetic response within medium 111 to display device 116 (shown in FIG. 1) such that the user may detect and/or identify a change in the dielectric constant for medium 111 when compared to the standard clean and uncontaminated oil sample that may be used in transformer 107. Diagnostic system 112 may also transmit each power difference signal to display device 116 via conduit 118. In the exemplary embodiment, display device 116 provides a graphical representation of each frequency shift and/or each power difference signal. Such representations may be provided to a user in the form of waveforms, charts, and/or graphs.

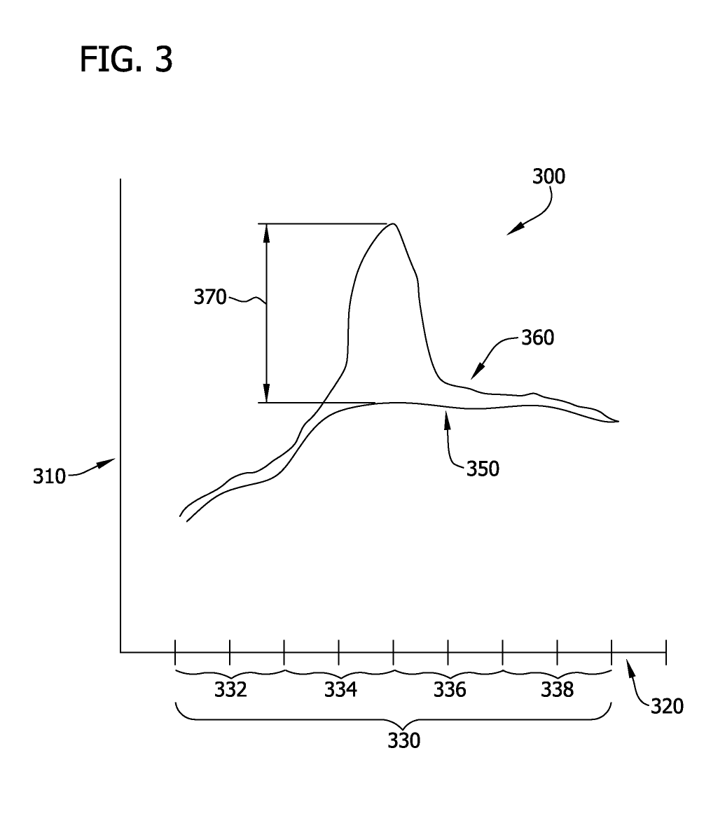

FIG. 3 is a graphical view of an exemplary power difference response 300 that may be generated by sensor assembly 110 (shown in FIGS. 1 and 2). More specifically, power difference response 300 is a comparison of an amount of power 310 (shown on the ordinate axis of FIG. 3) contained within the microwave signal at a specific frequency 320 in GHz (shown on the abscissa axis of FIG. 3). In the exemplary embodiment, signal generator 218 (shown in FIG. 2) generates microwave signals that include a plurality of frequency components within predefined frequency bands 330 that include a frequency range between approximately 1 GHz and approximately 20 GHz. In the exemplary embodiment, such frequency bands 330 include a first frequency band 332, a second frequency band 334, a third frequency band 336, and a fourth frequency band 338. More specifically, in the exemplary embodiment, second frequency band 334 is proportional to first frequency band 332 by a power of two. For example, first frequency band 332 includes frequencies between approximately 1 GHz and approximately 2 GHz, and second frequency band 334 includes frequencies between approximately 2 GHz to approximately 4 GHz. Moreover, third frequency band 336 includes frequencies between approximately 4 GHz to approximately 8 GHz. Further, fourth frequency band 338 includes frequencies between approximately 8 GHz and approximately 16 GHz. Alternatively, a user may generate any type of output and/or graphical representation of power difference response 300, such as a logarithmic and/or a linear scale representation, that is appropriate and/or suitable for the user's needs.

Moreover, in the exemplary embodiment, power difference response 300 compares an expected power level response curve 350 to an actual power level response curve 360. Expected power level response curve 350 includes an expected power level of each frequency received from emitter 206 (shown in FIG. 2), and actual power level response curve 360 includes an actual power level for each frequency received from emitter 206. If the difference between each actual power level and each expected power level is approximately zero, then medium 111 (shown in FIGS. 1 and 2) does not contain gaseous components therein and/or the presence of gaseous components within medium 111 is minimal. Alternatively, if the difference between each actual power level and each expected power level is greater than zero, then there is a presence of gaseous components within medium 111. Moreover, in the exemplary embodiment, an amplitude 370 generated in actual power level response curve 360 is approximately related to the quantity of the gaseous component within medium 111.

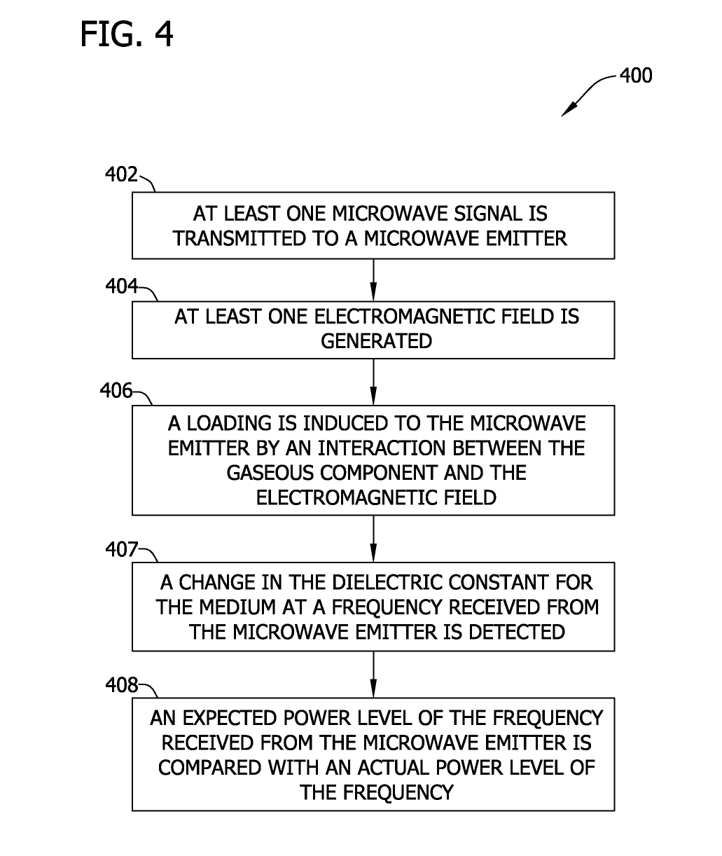

FIG. 4 is a flow diagram of an exemplary method 400 that may be implemented to determine the presence of materials (not shown), such as gaseous components, entrained within a medium 111 (shown in FIGS. 1 and 2) using a sensor assembly 110 (shown in FIGS. 1 and 2). In the exemplary embodiment, at least one microwave signal is transmitted 402 to a microwave emitter 206 (shown in FIG. 2). At least one electromagnetic field 209 (shown in FIG. 2) is generated 404 by microwave emitter 206 from the microwave signal. A loading is induced 406 to microwave emitter 206 by an interaction between the gaseous component and electromagnetic field 209. A change in the dielectric constant for medium 111 at a frequency received from microwave emitter 206 is detected 407. Moreover, an expected power level of the frequency received from microwave emitter 206 is compared 408 with an actual power level of the frequency in order to determine a presence of the gaseous component within medium 111.

As compared to known sensor assemblies, the embodiments described herein provide a sensor assembly that detects a change of the dielectric constant for a medium and determines the presence of at least one material within the medium in real-time that is the cause for the change in the dielectric constant. More specifically, the sensor assembly includes a probe that includes a microwave emitter, and at least one signal processing device that is coupled to the probe. The signal processing device is configured to detect a change in the dielectric constant for a medium at a frequency received from the microwave emitter and to compare an expected power level of the frequency received from the microwave emitter with an actual power level of the frequency in order to determine a presence of at least one material entrained within the medium. This comparison enables the sensor assembly to determine the presence of any gaseous components within the oil in a transformer.

Exemplary embodiments of a sensor assembly and methods for determining the presence of materials entrained within a medium are described above in detail. The methods and sensor assembly are not limited to the specific embodiments described herein, but rather, components of the sensor assembly and/or steps of the methods may be utilized independently and separately from other components and/or steps described herein. For example, the sensor assembly may also be used in combination with other measuring systems and methods, and is not limited to practice with only the power generation system as described herein. Rather, the exemplary embodiment can be implemented and utilized in connection with many other measurement and/or monitoring applications.

Although specific features of various embodiments of the invention may be shown in some drawings and not in others, this is for convenience only. In accordance with the principles of the invention, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A method for determining a presence of at least one material entrained within a medium, said method comprising:
transmitting at least one microwave signal to a microwave emitter;
generating, by the microwave emitter, at least one electromagnetic field from the at least one microwave signal;
detecting a change in the dielectric constant for the medium at a frequency received from the microwave emitter; and
comparing an expected power level of the frequency received from the microwave emitter with an actual power level of the frequency to determine a presence of the at least one material entrained within the medium.

2. A method in accordance with claim 1, further comprising inducing a loading to the microwave emitter by an interaction between the at least one material and the at least one electromagnetic field.

3. A method in accordance with claim 1, wherein transmitting at least one microwave signal to a microwave emitter further comprises transmitting at least one microwave signal including a plurality of frequency components within a predefined frequency range to the microwave emitter.

4. A method in accordance with claim 3, wherein transmitting at least one microwave signal including a plurality of frequency components further comprises transmitting at least one microwave signal including a plurality of frequency components between approximately 1 GHz and approximately 20 GHz to the microwave emitter.

5. A method in accordance with claim 1, wherein transmitting at least one microwave signal to a microwave emitter further comprises transmitting at least one microwave signal to a broadband emitter.

6. A method in accordance with claim 1, further comprising submerging the microwave emitter within the medium.

7. A method in accordance with claim 6, wherein submerging the microwave emitter comprises submerging the microwave emitter within a liquid medium.

8. A sensor assembly for use with a power generation system, said sensor assembly comprising:
at least one probe comprising a microwave emitter, said microwave emitter is configured to generate at least one electromagnetic field from at least one microwave signal; and
at least one signal processing device coupled to said at least one probe, wherein said at least one signal processing device is configured to detect a change in the dielectric constant of a medium at a frequency received from said microwave emitter and to compare an expected power level of the frequency received from said microwave emitter with an actual power level of the frequency in order to determine a presence of at least one material entrained within the medium.

9. A sensor assembly in accordance with claim 8, wherein a loading is induced to said microwave emitter when the at least one material interacts with the at least one electromagnetic field.

10. A sensor assembly in accordance with claim 8, wherein the at least one microwave signal comprises a plurality of frequency components within a predefined frequency range.

11. A sensor assembly in accordance with claim 10, wherein the predefined frequency range is between approximately 1 GHz and approximately 20 GHz.

12. A sensor assembly in accordance with claim 8, wherein said microwave emitter is a broadband emitter.

13. A sensor assembly in accordance with claim 8, wherein said microwave emitter is submerged within the medium.

14. A sensor assembly in accordance with claim 8, wherein the medium is a liquid medium.

15. A power generation system comprising:
a machine comprising at least one transformer including a medium contained therein;
a sensor assembly positioned proximate to said at least one transformer, said sensor assembly comprising:
at least one probe comprising a microwave emitter, said microwave emitter is configured to generate at least one electromagnetic field from at least one microwave signal; and
at least one signal processing device coupled to said at least one probe, wherein said at least one signal processing device is configured to detect a change in the dielectric constant of the medium at a frequency received from said microwave emitter and to compare an expected power level of the frequency received from said microwave emitter with an actual power level of the frequency in order to determine a presence of at least one material entrained within the medium.

16. A power generation system in accordance with claim 15, wherein a loading is induced to said microwave emitter when the at least one material interacts with the at least one electromagnetic field.

17. A power generation system in accordance with claim 15, wherein the at least one microwave signal comprises a plurality of frequency components within a predefined frequency range.

18. A power generation system in accordance with claim 17, wherein the predefined frequency range is between approximately 1 GHz and approximately 20 GHz.

19. A power generation system in accordance with claim 15, wherein said microwave emitter is a broadband emitter.

20. A power generation system in accordance with claim 15, wherein said microwave emitter is submerged within the medium.
